(19) United States
(12) Patent Application Publication
(10) Pub. No.: US 2010/0117128 A1
(43) Pub. Date: May 13, 2010

(54) SEMICONDUCTOR MEMORY DEVICE AND METHOD FOR MANUFACTURING THE SAME

(75) Inventors: Saku Hashiura, Kawasaki-Shi (JP); Yoshinori Kumura, Albany, NY (US); Tohru Ozaki, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/564,728

(22) Filed: Sep. 22, 2009

(30) Foreign Application Priority Data
Nov. 12, 2008 (JP) 2008-289698

(51) Int. Cl. H01L 27/108; H01L 21/8242

(52) U.S. Cl. 257/295; 438/3; 257/E27.084; 257/E21.646

(57) ABSTRACT

A semiconductor memory device has a semiconductor substrate, an impurity diffusion layer that is formed at a surface portion of the semiconductor substrate, an interlayer insulating film that is formed on the semiconductor substrate, a contact plug that penetrates the interlayer insulating film, has a top surface formed higher than a top surface of the interlayer insulating film, a region having a convex shape formed higher than the top surface of the interlayer insulating film, and contacts the impurity diffusion layer, a lower capacitor electrode film that is formed on the contact plug and a predetermined region of the interlayer insulating film, a ferroelectric film that is formed on the lower capacitor electrode film, and an upper capacitor electrode film that is formed on the ferroelectric film.

### CROSS REFERENCE TO RELATED APPLICATION

This application is based upon and claims benefit of priority from the Japanese Application No. 2008-289698, filed on Nov. 12, 2008, the entire contents of which are incorporated herein by reference.

### BACKGROUND OF THE INVENTION

The present invention relates to a semiconductor memory device and a method for manufacturing the same.

In recent years, attention is drawn to ferroelectric memories (or FeRAM: Ferroelectric Random Access Memory) as one type of semiconductor memories. A ferroelectric memory is a nonvolatile memory that includes a ferroelectric film such as a PZT (Pb(ZrₓTi₁₋ₓ)O₃) film, a BIT (Bi₄Ti₃O₁₂) film, or a SBT (SrBi₂Ta₂O₉) film at each capacitor portion, and stores data by virtue of the residual polarization of the ferroelectric film. A capacitor is formed on a semiconductor substrate, and an impurity diffusion layer that is formed on a surface of the semiconductor substrate are connected with a lower electrode film of the capacitor by a contact plug (for example, refer to JP-A 8-335673 (KOKAI)).

In a conventional ferroelectric memory, an interlayer insulating film is formed to cover a transistor formed on a semiconductor substrate, a contact hole is opened to expose a surface of an impurity diffusion layer formed on a surface of the semiconductor substrate, tungsten is used to form a film through a chemical vapor deposition (CVD) method to bury the contact hole, and a chemical mechanical polishing (CMP) process is performed using the interlayer insulating film as a stopper, and a contact plug is formed. If an Ir film that is a lower electrode film of the capacitor is formed on the contact plug formed in this way, a grain (single-crystal lump) is likely to be generated in the Ir film. If the grain is formed in the lower electrode film, oxygen that is contained in a ferroelectric film formed on the lower electrode film is likely to diffuse into the contact plug through a grain interface. If the contact plug is oxidized due to the diffusion of the oxygen, a voltage is not normally applied to the ferroelectric film, operation performance of the ferroelectric memory is deteriorated, and reliability is lowered.

### SUMMARY OF THE INVENTION

According to one aspect of the present invention, there is provided a semiconductor memory device comprising:

a semiconductor substrate;

an impurity diffusion layer that is formed at a surface portion of the semiconductor substrate;

an interlayer insulating film that is formed on the semiconductor substrate;

a contact plug that penetrates the interlayer insulating film, has a top surface formed higher than a top surface of the interlayer insulating film, a region having a convex shape formed higher than the top surface of the interlayer insulating film, and contacts the impurity diffusion layer;

a lower capacitor electrode film that is formed on the contact plug and a predetermined region of the interlayer insulating film;

a ferroelectric film that is formed on the lower capacitor electrode film; and

an upper capacitor electrode film that is formed on the ferroelectric film.

According to one aspect of the present invention, there is provided a semiconductor memory device comprising:

a semiconductor substrate;

first to third impurity diffusion layers that are formed at a surface portion of the semiconductor substrate at predetermined intervals;

a first interlayer insulating film that is formed on the semiconductor substrate;

a first contact plug that is formed in the first interlayer insulating film and is connected to the first impurity diffusion layer;

a second contact plug that is formed in the first interlayer insulating film and is connected to the second impurity diffusion layer;

a third contact plug that is formed in the first interlayer insulating film and is connected to the third impurity diffusion layer;

a fourth contact plug that is formed on the first contact plug and has first and second convex portions formed on a top surface thereof;

a fifth contact plug that is formed on the second contact plug;

a sixth contact plug that is formed on the third connect plug and has third and fourth convex portions formed on a top surface thereof;

a first capacitor that is formed on the first convex portion and has a lower electrode film, a ferroelectric film, and an upper electrode film, which are sequentially laminated;

a second capacitor that is formed on the second convex portion and has a lower electrode film, a ferroelectric film, and an upper electrode film, which are sequentially laminated;

a third capacitor that is formed on the third convex portion and has a lower electrode film, a ferroelectric film, and an upper electrode film, which are sequentially laminated;

a fourth capacitor that is formed on the fourth convex portion and has a lower electrode film, a ferroelectric film, and an upper electrode film, which are sequentially laminated;

a second interlayer insulating film that is formed to cover the first to fourth capacitors and the first to third contact plugs;

a seventh contact plug that is formed in the second interlayer insulating film and is connected to the fifth contact plug;

an eight contact plug that is formed in the second interlayer insulating film and is connected to the upper electrode film of the first capacitor;

a ninth contact plug that is formed in the second interlayer insulating film and is connected to the upper electrode film of the third capacitor; and

a wiring layer that is formed on the second interlayer insulating film and is connected to the seventh to ninth contact plugs.

According to one aspect of the present invention, there is provided a method for manufacturing a semiconductor memory device, comprising:

forming an impurity diffusion layer at a surface portion of a semiconductor substrate;

forming an interlayer insulating film on the semiconductor substrate:

forming an opening penetrating the interlayer insulating film and exposing a top surface of the impurity diffusion layer;

burying a metal film in the opening;

removing the interlayer insulating film from a top surface with a predetermined thickness to expose an upper portion of the metal film;

performing a chemical mechanical polishing (CMP) process to remove an upper end of the metal film; and

forming a capacitor having a lower electrode film, a ferroelectric film, and an upper electrode film, which are sequentially laminated, on the metal film.

According to one aspect of the present invention, there is provided a method for manufacturing a semiconductor memory device, comprising:

forming an impurity diffusion layer at a surface portion of a semiconductor substrate;

forming an interlayer insulating film on the semiconductor substrate;

forming an opening penetrating the interlayer insulating film and exposing a top surface of the impurity diffusion layer;

burying a first metal film in the opening;

removing the interlayer insulating film from a top surface with a predetermined thickness to expose an upper portion of the first metal film;

forming a second metal film having a convex shape in an outer circumferential portion of the first metal film on the interlayer insulating film; and

forming a capacitor having a lower electrode film, a ferroelectric film, and an upper electrode film, which are sequentially laminated, on the first and second metal films.

According to one aspect of the present invention, there is provided a method for manufacturing a semiconductor memory device, comprising:

forming first to third impurity diffusion layers at a surface portion of a semiconductor substrate at predetermined intervals;

forming a first interlayer insulating film on the semiconductor substrate;

forming first to third openings penetrating the first interlayer insulating film and exposing top surfaces of the first to third impurity diffusion layers, respectively;

burying a first metal film in the first to third openings to form first to third contact plugs;

forming a second interlayer insulating film on the first interlayer insulating film and the first to third contact plugs;

forming a fourth opening penetrating the second interlayer insulating film and exposing a top surface of the first contact plug, a fifth opening exposing a top surface of the second contact plug and having a width narrower than that of the fourth opening, and a sixth opening exposing a top surface of the third contact plug and having a width wider than that of the fifth opening;

burying a second metal film in the fourth to sixth openings to form fourth to sixth contact plugs;

forming a resist film in first and second predetermined regions on the fourth contact plug and third and fourth predetermined regions on the sixth contact plug;

removing the second interlayer insulating film and the fourth to sixth contact plugs with a predetermined thickness, using the resist film as a mask;

removing the resist film;

performing a chemical mechanical polishing (CMP) process to remove an upper end of the fourth contact plug of the first and second predetermined regions and an upper end of the sixth contact plug of the third and fourth predetermined regions;

forming first to fourth capacitors having a lower electrode film, a ferroelectric film, and an upper electrode film, which are sequentially laminated, in the first and second predetermined regions on the fourth contact plug and the third and fourth predetermined regions on the sixth contact plug, respectively;

forming a third interlayer insulating film to cover the first to fourth capacitors, the second interlayer insulating film, and the fourth to sixth contact plugs;

forming a seventh opening penetrating the third interlayer insulating film and exposing a top surface of the fifth contact plug;

burying a third metal film in the seventh opening to form a seventh contact plug;

forming eighth and ninth openings penetrating the third interlayer insulating film and exposing a top surface of the upper electrode film of the first capacitor and a top surface of the upper electrode film of the third capacitor, respectively;

burying a fourth metal film in the eighth and ninth openings to form eighth and ninth contact plugs;

forming a fourth interlayer insulating film on the third interlayer insulating film and the seventh to ninth contact plugs;

forming a tenth opening penetrating the fourth interlayer insulating film and exposing top surfaces of the seventh to ninth contact plugs; and

burying a fifth metal film in the tenth opening to form a wiring layer contacting the seventh to ninth contact plugs.

### BRIEF DESCRIPTION OF THE DRAWINGS

FIG. 1 is a cross-sectional view illustrating a semiconductor memory device according to a first embodiment of the present invention;

FIG. 2 is a view illustrating a section SEM image of the semiconductor memory device according to the first embodiment;

FIG. 3 is a view illustrating a section SEM image of the semiconductor memory device according to a comparative example;

FIG. 4 is a process sectional view for explaining a manufacturing method of the semiconductor memory device according to the first embodiment;

FIG. 5 is a process sectional view showing a step subsequent to FIG. 4;

FIG. 6 is a process sectional view showing a step subsequent to FIG. 5;

FIG. 7 is a process sectional view showing a step subsequent to FIG. 6;

FIG. 8 is a process sectional view showing a step subsequent to FIG. 7;

FIG. 9 is a process sectional view showing a step subsequent to FIG. 8;

FIG. 10 is a process sectional view showing a step subsequent to FIG. 9;

FIG. 11 is a process sectional view showing a step subsequent to FIG. 10;

FIG. 12 is a process sectional view for explaining a manufacturing method of a semiconductor memory device according to a first modification;

FIG. 13 is a process sectional view showing a step subsequent to FIG. 12;

FIG. 14 is a process sectional view showing a step subsequent to FIG. 13;

FIG. 15 is a process sectional view for explaining a manufacturing method of a semiconductor memory device according to a second modification;

FIG. 16 is a process sectional view showing a step subsequent to FIG. 15;

FIG. 17 is a process sectional view showing a step subsequent to FIG. 16;

FIG. 18 is a process sectional view showing a step subsequent to FIG. 17;

FIG. 19 is a process sectional view showing a step subsequent to FIG. 18;

FIG. 20 is a cross-sectional view illustrating a semiconductor memory device according to a second embodiment of the present invention;

FIG. 21 is a process sectional view for explaining a manufacturing method of a semiconductor memory device according to the second embodiment;

FIG. 22 is a process sectional view showing a step subsequent to FIG. 21;

FIG. 23 is a process sectional view showing a step subsequent to FIG. 22;

FIG. 24 is a process sectional view showing a step subsequent to FIG. 23;

FIG. 25 is a process sectional view for explaining a manufacturing method of a semiconductor memory device according to a third modification;

FIG. 26 is a process sectional view showing a step subsequent to FIG. 25;

FIG. 27 is a process sectional view showing a step subsequent to FIG. 26;

FIG. 28 is a process sectional view showing a step subsequent to FIG. 27;

FIG. 29 is a process sectional view showing a step subsequent to FIG. 28;

FIG. 30 is a process sectional view showing a step subsequent to FIG. 29;

FIG. 31 is a process sectional view for explaining a manufacturing method of a semiconductor memory device according to a third embodiment;

FIG. 32 is a process sectional view showing a step subsequent to FIG. 31;

FIG. 33 is a process sectional view showing a step subsequent to FIG. 32;

FIG. 34 is a process sectional view showing a step subsequent to FIG. 33;

FIG. 35 is a process sectional view showing a step subsequent to FIG. 34;

FIG. 36 is a process sectional view showing a step subsequent to FIG. 35;

FIG. 37 is a process sectional view showing a step subsequent to FIG. 36; and

FIG. 38 is a process sectional view showing a step subsequent to FIG. 37.

### DESCRIPTION OF THE EMBODIMENTS

Hereinafter, embodiments of the present invention will be described in detail with reference to the accompanying drawings.

### First Embodiment

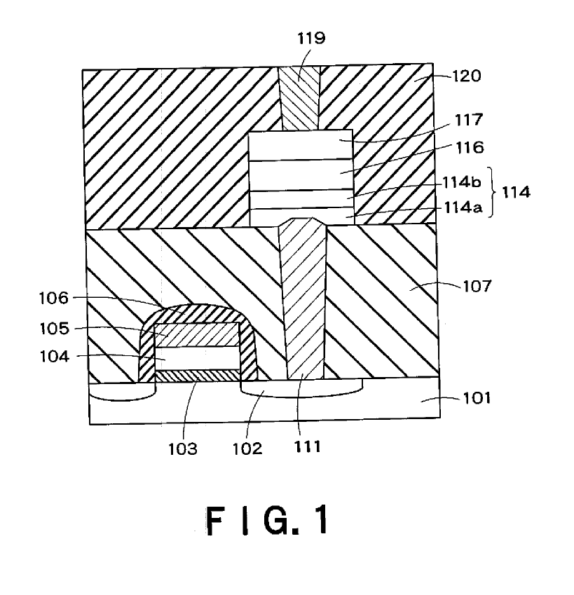

FIG. 1 shows the schematic configuration of a semiconductor memory device according to a first embodiment of the present invention. On a semiconductor substrate 101, a MOS transistor is formed. The MOS transistor is formed using a gate insulating film 103, a gate electrode (for example, polycide structure including a polysilicon film 104 and a tungsten silicide film 105) that is a word line, a gate sidewall film 106 and a gate cap film including a silicon nitride film, and a source/drain diffusion layer 102.

An interlayer insulating film 107 (silicon oxide film) is formed to surround the MOS transistor.

In the interlayer insulating film 107, a contact plug 111 is formed, which connects the source/drain diffusion layer 102 of the MOS transistor and a lower electrode 114 of a capacitor. The contact plug 111 is, for example, made of tungsten.

As viewed from a top surface of the interlayer insulating film 107, an upper portion of the contact plug 111 has a convex structure. A width of the contact plug 111 in a horizontal direction becomes narrowed when a position of the contact plug in a vertical direction becomes low (becomes close to the semiconductor substrate 101) in the interlayer insulating film 107. In a region of the contact plug 111 that is formed higher than the top surface of the interlayer insulating film 107, the width of the contact plug 111 becomes narrowed when the position of the contact plug in the vertical direction becomes high. That is, a side of the region of the contact plug 111 that is formed higher than the top surface of the interlayer insulating film 107 forms an angle θ (90°<θ<180°) with respect to a top surface of the interlayer insulating film 107 surrounding the contact plug 111.

The capacitor is formed on the interlayer insulating film 107. The capacitor has a lower electrode 114, a ferroelectric film 116, and an upper electrode 117, which are sequentially laminated.

An interlayer insulating film (silicon oxide film) 120 is formed to surround the entire region of the capacitor, and a contact 119 that contacts the upper electrode 117 is formed in the interlayer insulating film 120. The contact 119 is used, for example, to connect the upper electrodes of the adjacent capacitors each other.

The lower electrode 114 includes a TiAlN film 114a and an Ir film (noble metal film) 114b that is a barrier layer. A bottom surface of the Ir film 114b is formed in a higher position than the top surface of the contact plug 111. For example, the ferroelectric film 116 is composed of a PZT film and the upper electrode 117 is composed of an IrO₂ film.

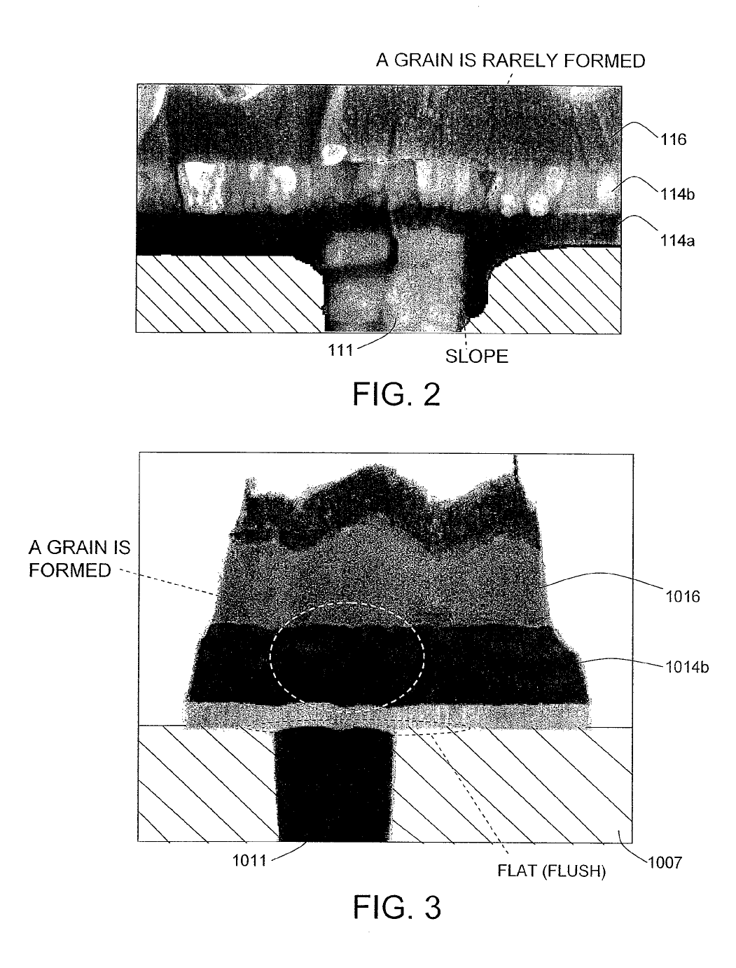

FIG. 2 shows a section scanning electron microscope (SEM) image of an upper portion of the contact plug 111 and the lower electrode 114. From FIG. 2, it can be seen that the Ir film 114b of the lower electrode 114 is formed to be almost uniform and a grain is rarely formed.

FIG. 3 shows a section SEM image of when an upper portion of a contact plug 1011 is flat, that is, a top surface of the contact plug 1011 and a top surface of an interlayer insulating film 1007 are flush with each other, as a comparative example. From FIG. 3, it can be seen that a place where contrast varies exists in an Ir film 1014b over the contact plug 1011. The place where the contrast varies shows that a grain is formed. If the grain is formed in the Ir film 1014b, oxygen of the ferroelectric film 1016 diffuses through the grain interface, and oxidizes the contact plug 1011.

Meanwhile, in this embodiment, the grain is rarely formed in the Ir film 114b of the lower electrode 114, and the oxygen that is contained in the ferroelectric film 116 is prevented from diffusing into the contact plug 111. Since oxidization of the contact plug is suppressed, a voltage can be normally applied to the ferroelectric film, and operation performance of a ferroelectric memory can be improved. Accordingly, a semiconductor memory device having high reliability can be realized.

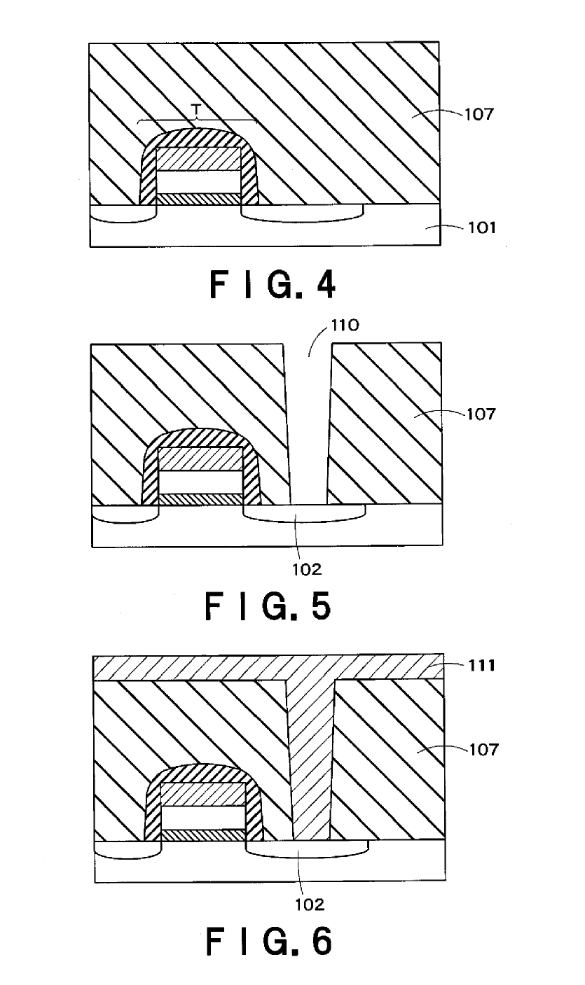

A method of manufacturing the semiconductor memory device will be described using FIGS. 4 to 11.

As shown in FIG. 4, a transistor T is built in a silicon substrate 101 using a known process to form a CMOS structure. In addition, a silicon oxide film 107 is deposited using a chemical vapor deposition (CVD) method and a chemical mechanical polishing (CMP) process to form an interlayer insulating film.

As shown in FIG. 5, a contact hole 110 that is used to expose a surface of an impurity diffusion layer 102 of the transistor T is opened using a lithography technology and a reactive ion etching (RIE) method.

As shown in FIG. 6, a tungsten film 111 is formed using the CVD method to bury the contact hole 110.

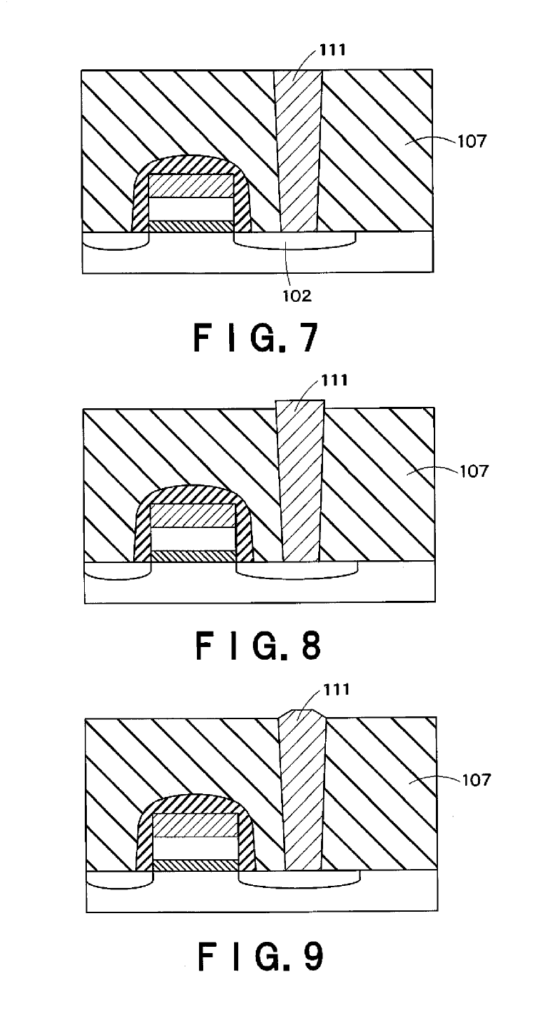

As shown in FIG. 7, the CMP process is performed using the silicon oxide film 107 as a stopper to planarize a top surface of a tungsten film 111 and a top surface of the silicon oxide film 107.

As shown in FIG. 8, overall etching is performed under the condition where an etching rate of the silicon oxide film is faster than an etching rate of the tungsten film. Thereby, an upper portion of the tungsten film 111 has a convex shape as viewed from the top surface of the silicon oxide film 107.

As shown in FIG. 9, an upper end of the tungsten film 111 is removed by performing the CMP process, and a step between the top surface of the tungsten film 111 and the top surface of the silicon oxide film 107 are smoothened.

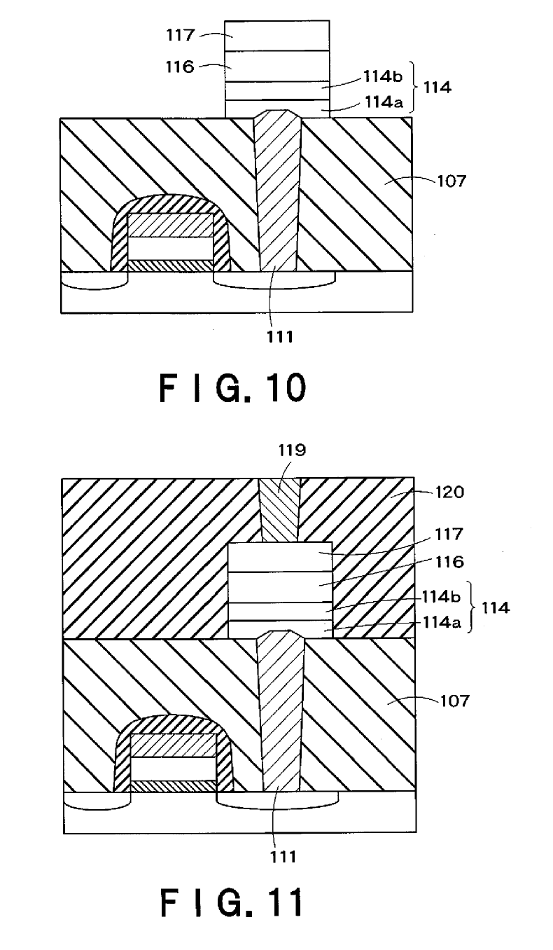

As shown in FIG. 10, on the silicon oxide film 107 and the tungsten film 111, a barrier layer 114a composed of a TiAlN film, a noble metal film 114b composed of an Ir film, a ferroelectric film 116 composed of a PZT film, and an upper electrode film 117 composed of an IrO₂ film are sequentially laminated. In addition, RIE processing is performed using a hard mask (not shown), and a capacitor structure is formed.

As shown in FIG. 11, after the hard mask is removed, an interlayer insulating film (silicon oxide film) 120 is formed, and a contact 119 that is connected to the upper electrode 117 is formed in the interlayer insulating film 120.

In this way, a semiconductor memory device where the upper portion of the contact plug 111 has a convex structure below the lower electrode 114 is obtained. A grain is rarely formed in the Ir film 114b of the lower electrode 114, and oxygen that is contained in the ferroelectric film 116 is prevented from diffusing into the contact plug 111.

Since oxidization of the contact plug is suppressed, a voltage can be normally applied to the ferroelectric film, and operation performance of a ferroelectric memory can be improved. Accordingly, a semiconductor memory device having high reliability can be manufactured.

Further, even though the noble metal film of the lower electrode is thinner, oxidation resistance can be maintained. Therefore, a capacitor size can be reduced, and it is preferable that a capacity of the ferroelectric memory can be increased.

### First Modification

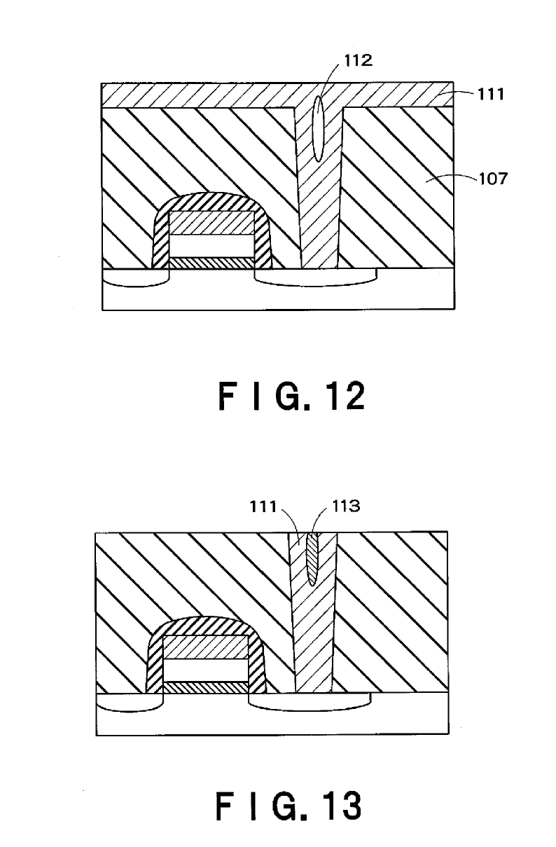

In the first embodiment, when the tungsten film 111 shown in FIG. 6 is formed, the tungsten film 111 is not buried in the contact hole 110. As shown in FIG. 12, a cavity 112 may be formed in a central portion of the contact hole 110.

In this case, as shown in FIG. 13, after the CMP process is performed using the silicon oxide film 107 as a stopper, a conductive material 113 may be buried in the cavity 112. Examples of the conductive material 113 may include tungsten, aluminum, and TiN.

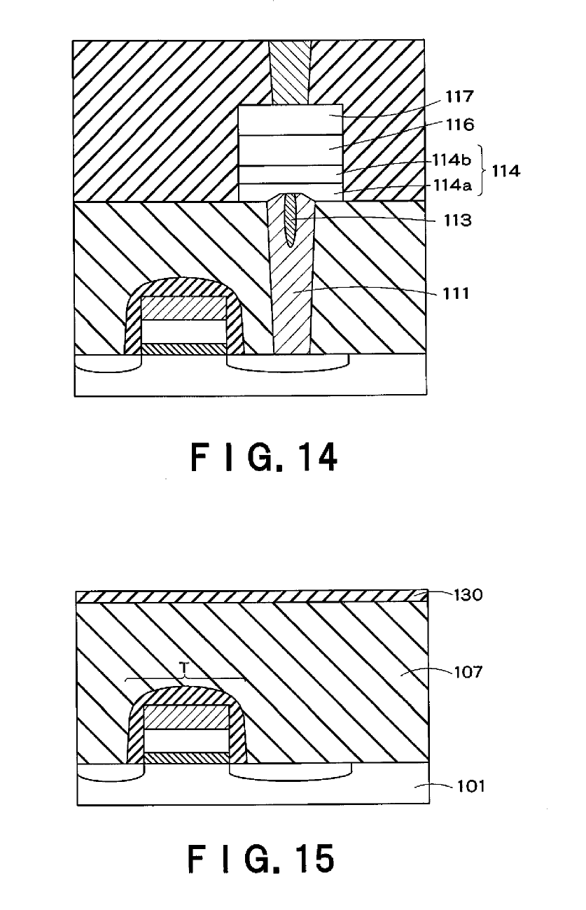

Thereafter, if the same processes as the processes according to the first embodiment shown in FIGS. 8 to 11 are performed, a semiconductor memory device where the conductive material 113 is buried in the central portion of the contact plug 111 is obtained, as shown in FIG. 14. Even in this semiconductor memory device, the same effect as the semiconductor memory device according to the first embodiment shown in FIG. 1 can be obtained.

### Second Modification

A method of manufacturing a semiconductor memory device according to a second modification will be described.

As shown in FIG. 15, a transistor T is built in a silicon substrate 101 using a known process to form a CMOS structure. In addition, a silicon oxide film 107 is deposited using the CVD method and the CMP process to form an interlayer insulating film. Subsequently, a silicon nitride film 130 is formed on the silicon oxide film 107.

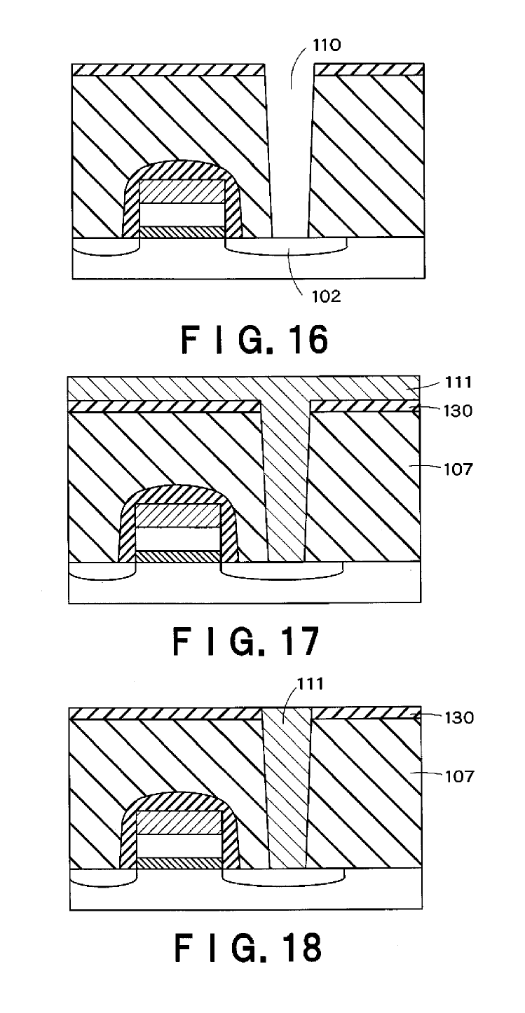

As shown in FIG. 16, a contact hole 110 that is used to expose a surface of an impurity diffusion layer 102 of the transistor T is opened using the lithography technology and the RIE method.

As shown in FIG. 17, a tungsten film 111 is formed using the CVD method to bury the contact hole 110.

As shown in FIG. 18, the CMP process is performed using the silicon nitride film 130 as a stopper to planarize a top surface of the tungsten film 111 and a top surface of the silicon nitride film 130.

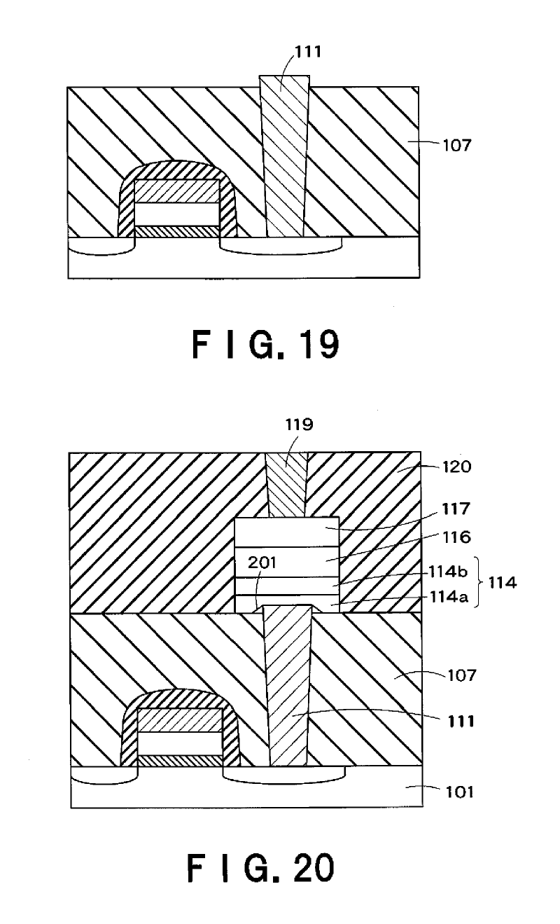

As shown in FIG. 19, the silicon nitride film 130 is removed using a phosphoric acid. Thereafter, if the same processes as the processes according to the first embodiment shown in FIGS. 8 to 11 are performed, the same structure as the semiconductor memory device according to the first embodiment shown in FIG. 1 is obtained.

### Second Embodiment

FIG. 20 shows the schematic configuration of a semiconductor memory device according to a second embodiment of the present invention. The same components as the components of the semiconductor memory device according to the first embodiment shown in FIG. 1 are denoted by the same reference numerals, and the description will not be repeated here.

In the semiconductor memory device according to this embodiment, a conductive material film 201 is provided in an outer circumferential portion of an upper portion (a portion that is formed higher than a top surface of an interlayer insulating film 107) of a contact plug 111. A shape of when the upper portion of the contact plug 111 and the conductive material film 201 are combined has a convex structure where a side has a taper angle as viewed from the top surface of the interlayer insulating film 107, similar to the upper portion of the contact plug 111 in the semiconductor memory device according to the first embodiment. Accordingly, in the shape of when the upper portion of the contact plug 111 and the conductive material film 201 are combined, a width of the contact plug 111 in a horizontal direction becomes narrowed when a position of the contact plug in a vertical direction becomes high, in a region of the contact plug that is formed higher than the top surface of the interlayer insulating film 107.

For this reason, similar to the first embodiment, a grain is prevented from being generated in a noble metal film (Ir film) 114b of a lower electrode 114, and oxidization of the contact plug 111 is suppressed, which results in obtaining a semiconductor memory device having high reliability.

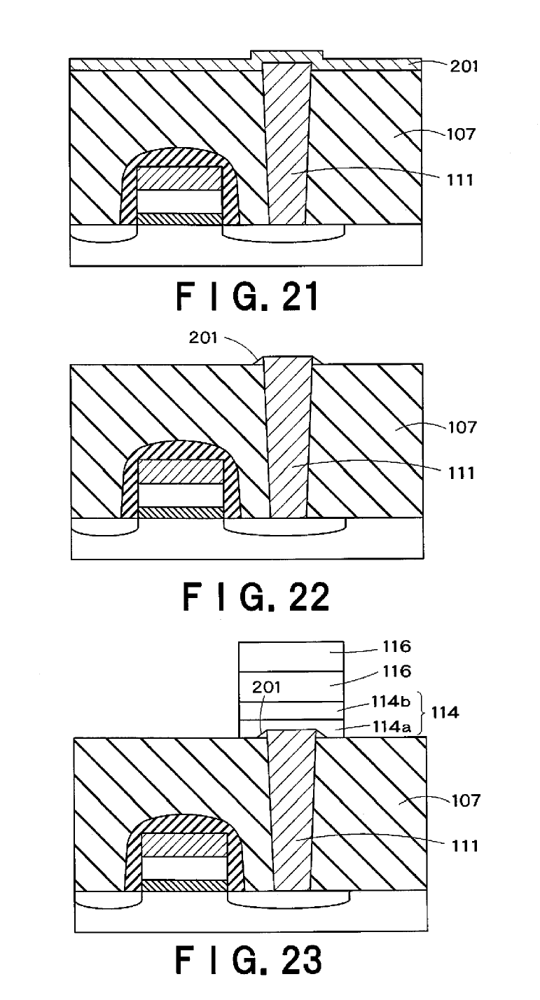

A method of manufacturing the semiconductor memory device will be described using FIGS. 21 to 24. The same processes as those in the first embodiment (shown FIGS. 4 to 8) are performed until the transistor T is built in the silicon substrate 101, the silicon oxide film (interlayer insulting film) 107 is deposited, the contact hole 110 is formed, the tungsten film 111 is formed, the CMP process is performed, and the overall etching is performed. Accordingly, the detailed description and illustration will not be repeated here.

As shown in FIG. 21, a conductive material film 201 is formed to cover the silicon oxide film 107 and the tungsten film 111. For example, the conductive material film 201 can be formed using tungsten, aluminum, or TiN.

As shown in FIG. 22, an etch back process is performed to expose the top surface of the tungsten film 111 and the top surface of the silicon oxide film 107. At this time, the conductive material film 201 of the outer circumferential portion of the tungsten film 111 remains.

As shown in FIG. 23, on the silicon oxide film 107, the tungsten film 111, and the conductive material film 201, a barrier layer 114a composed of a TiAlN film, a noble metal film 114b composed of an Ir film, a ferroelectric film 116 composed of a PZT film, and an upper electrode film 117 composed of an IrO₂ film are sequentially laminated. A bottom surface of the noble metal film 114b is formed higher than a top surface of the tungsten film 111. In addition, RIE processing is performed using a hard mask (not shown), and a capacitor structure is formed.

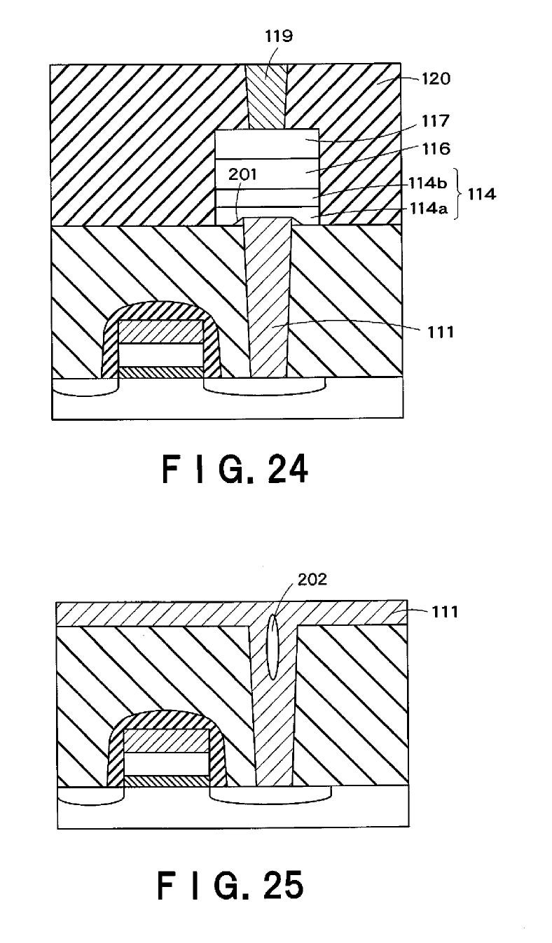

As shown in FIG. 24, after the hard mask is removed, an interlayer insulating film (silicon oxide film) 120 is formed, and a contact 119 that is connected to the upper electrode 117 is formed in the interlayer insulating film 120.

In this way, a semiconductor memory device where the upper portion of the contact plug 111 has a convex structure below the lower electrode 114 is obtained. A grain is rarely formed in the Ir film 114b of the lower electrode 114, and oxygen that is contained in the ferroelectric film 116 is prevented from diffusing into the contact plug 111.

Since oxidization of the contact plug is suppressed, a voltage can be normally applied to the ferroelectric film, and operation performance of a ferroelectric memory can be improved. Accordingly, a semiconductor memory device having high reliability can be manufactured.

During the process shown in FIG. 22, the conductive material film 201 other than the outer circumferential portion of the tungsten film 111 is removed using the etch back process, but may be removed using the CMP process.

### Third Modification

In the second embodiment, when the tungsten film 111 is buried in the contact hole 110, as shown in FIG. 25, the cavity 202 may be formed in the central portion of the contact hole 110.

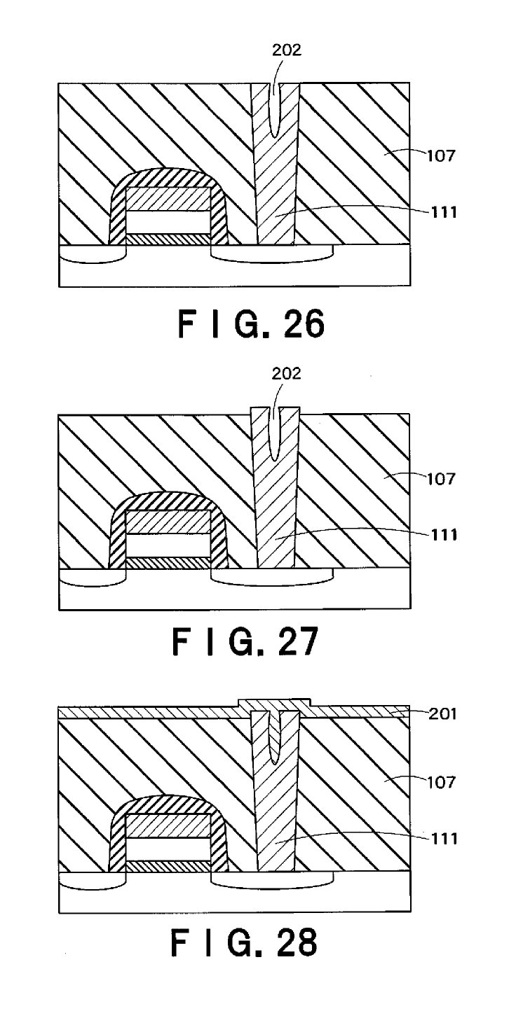

In this case, as shown in FIG. 26, the CMP process is performed such that the top surface of the silicon oxide film 107 is exposed, and the tungsten film 111 is planarized. Thereby, an upper portion of the cavity 202 is opened.

Subsequently, as shown in FIG. 27, overall etching is performed under the condition where an etching rate of the silicon oxide film is faster than an etching rate of the tungsten film. Thereby, the upper portion of the tungsten film 111 has a convex shape as viewed from the top surface of the silicon oxide film 107.

Subsequently, as shown in FIG. 28, the conductive material film 201 is formed to bury the cavity 202.

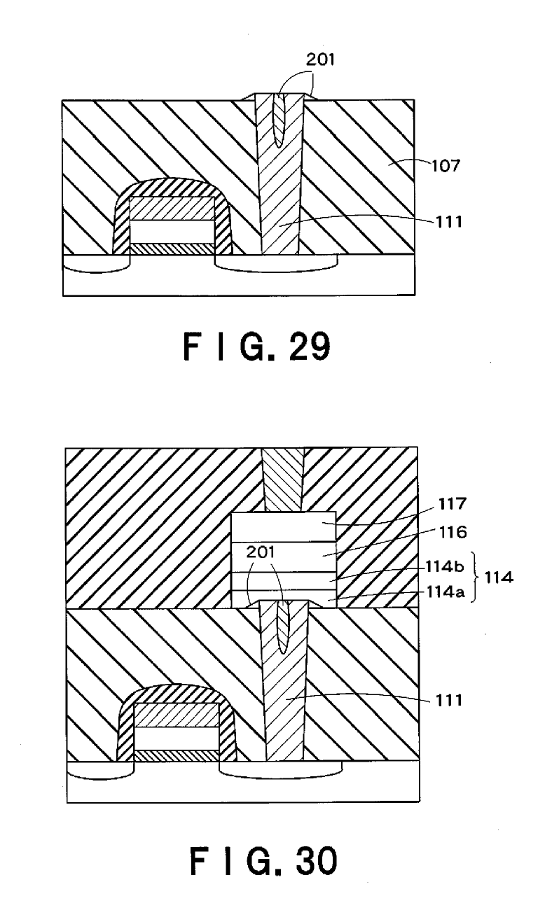

In addition, as shown in FIG. 29, the top surface of the silicon oxide film 107 is exposed using the etch back process or the CMP process. Thereby, the conductive material film 201 other than the outer circumferential portion of the tungsten film 111 and the inner portion (portion corresponding to the cavity 202) of the tungsten film 111 is removed.

Thereafter, if the same processes as the processes shown in FIGS. 23 and 24 are performed, a semiconductor memory device where the conductive material film 201 is formed in the outer circumferential portion and the central portion of the contact plug 111 is obtained, as shown in FIG. 30. Even in this semiconductor memory device, the same effect as the semiconductor memory device according to the second embodiment shown in FIG. 20 can be obtained.

### Third Embodiment

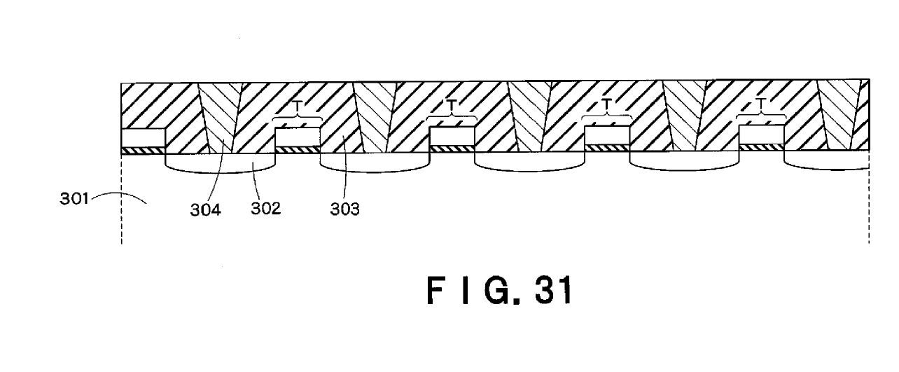

A method of manufacturing a semiconductor memory device according to a third embodiment of the present invention will be described using FIGS. 31 to 38. The semiconductor memory device according to this embodiment is a ferroelectric memory that has a structure of a chain (chain-like equivalent circuit), in which a ring where one transistor and one capacitor are connected in parallel is used as one memory cell, and plural (for example, 8) memory cells are connected in series.

As shown in FIG. 31, a plurality of transistors T are formed on a semiconductor substrate 301 at predetermined intervals, a silicon oxide film is formed to cover the transistors T, and an interlayer insulating film 303 is formed. A contact hole (not shown) is formed in the interlayer insulating film 303 to expose a top surface of an impurity diffusion layer 302 of each transistor T, for example a tungsten film is buried in the contact hole to form a contact plug 304.

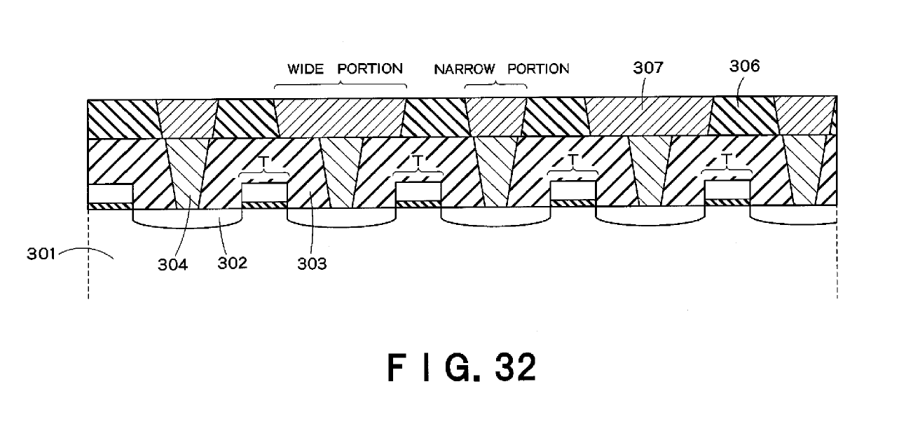

As shown in FIG. 32, for example, a silicon oxide film is deposited on the contact plug 304 and the interlayer insulating film 303, thereby forming an interlayer insulating film 306. In addition, an opening pattern that is used to expose a top surface of the contact plug 304 is formed, and a tungsten film is buried in the opening to form a contact plug 307.

In the opening pattern, wide openings and narrow openings are alternately formed. That is, in the contact plug 307, wide portions and narrow portions are alternately formed.

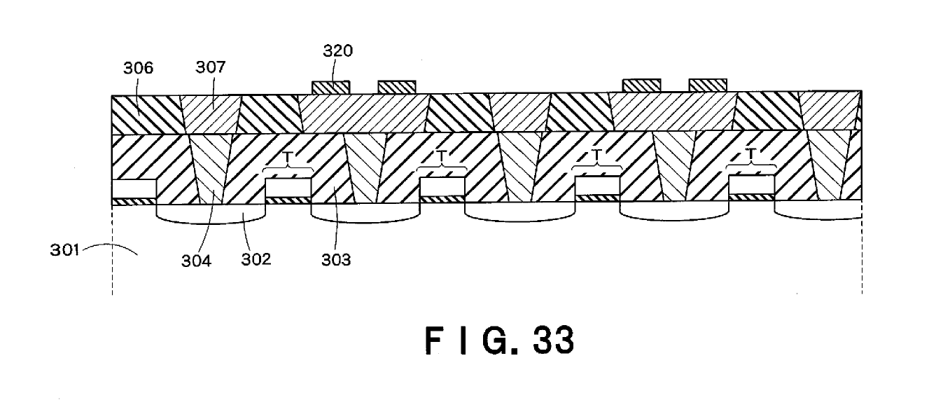

As shown in FIG. 33, a resist film 308 is coated on the interlayer insulating film 306 and the contact plug 307. In addition, the resist film 308 is processed using a lithography technology such that a predetermined wide region on the contact plug 307 remains. In this case, the region where the resist film 308 remains is a region where a capacitor is formed during the following process.

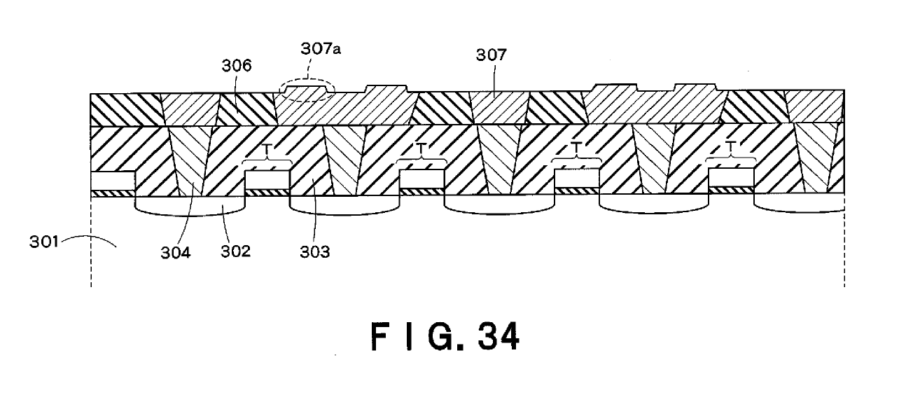

As shown in FIG. 34, the contact plug 307 and the interlayer insulating film 306 are partly removed using the resist film 308 as a mask. Thereafter, the resist film 308 is removed by ashing. After the resist film 308 is removed, the CMP process is performed to smoothen a step between a portion 307a masked by the resist film 308 and a portion not masked by the resist film 308 in the contact plug 307.

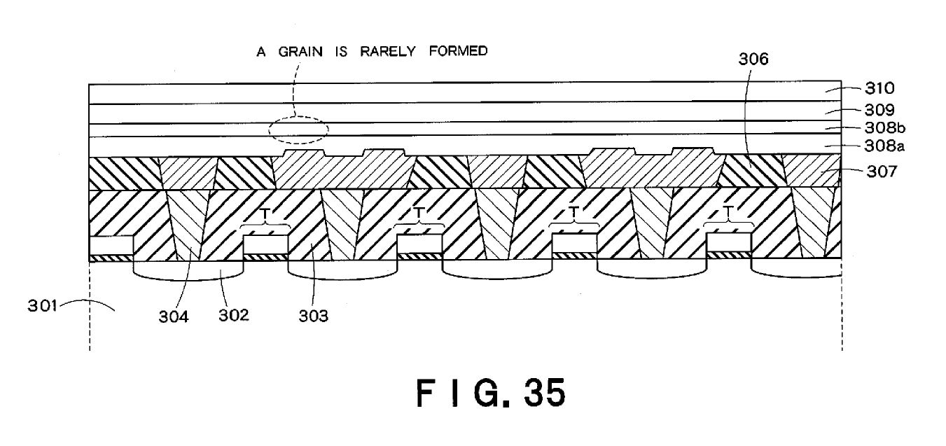

As shown in FIG. 35, on the contact plug 307 and the interlayer insulating film 306, a barrier layer 308a composed of a TiAlN film, a noble metal film 308b composed of an Ir film, a ferroelectric film 309 composed of a PZT film, and an upper electrode film 310 composed of an IrO₂ film are sequentially laminated.

Similar to the first embodiment, since the upper portion of the contact plug 307 has a convex structure as viewed from the top surface of the interlayer insulating film 306, a grain is rarely formed in the Ir film 308b.

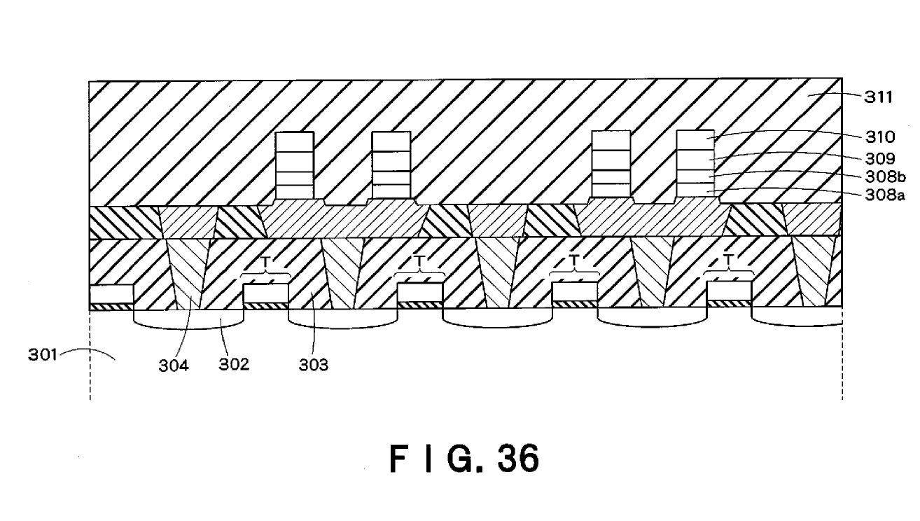

As shown in FIG. 36, RIE processing is performed using a hard mask (not shown), and a capacitor structure is formed. In addition, an interlayer insulating film 311 that is composed of a silicon oxide film is formed to cover the capacitor.

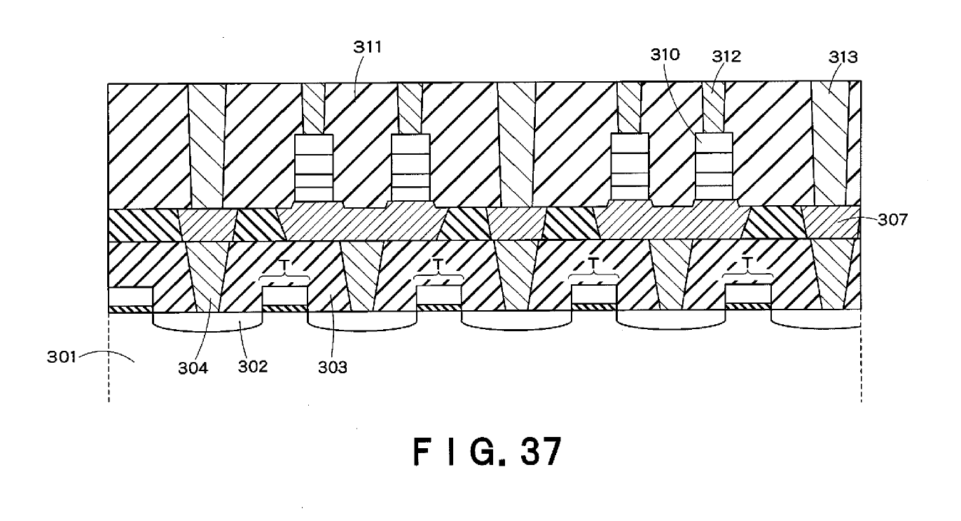

As shown in FIG. 37, a contact plug 312 that is connected to an upper electrode film 310 of each capacitor is formed. Subsequently, an opening pattern is formed to expose the top surface of the narrow contact plug 307, and a tungsten film is buried in the opening pattern to form a contact plug 313.

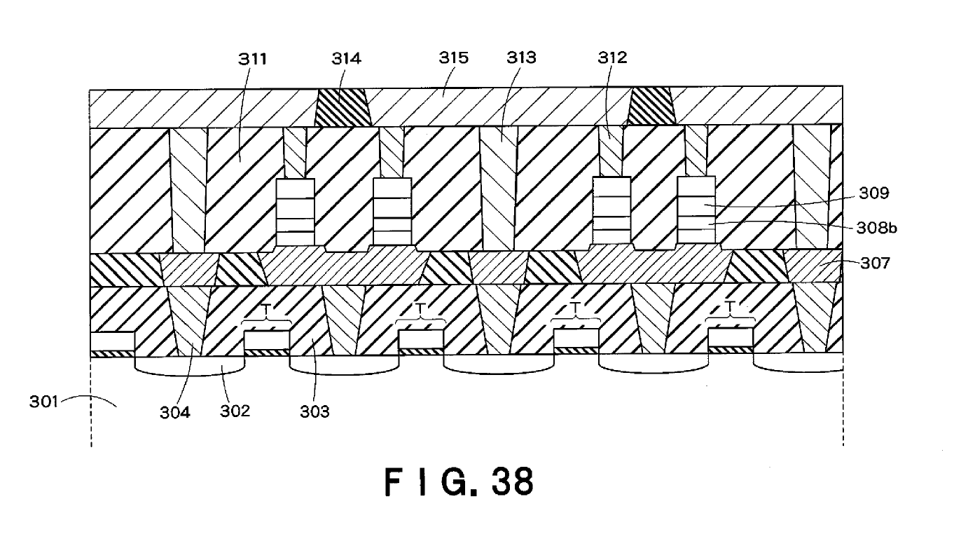

As shown in FIG. 38, an interlayer insulating film 314 that is composed of a silicon oxide film is formed on the interlayer insulating film 311 and the contact plugs 312 and 313. In addition, an opening pattern is formed to expose the top surfaces of the contact plugs 312 and 313, and for example, a tungsten film is buried in the opening pattern to form a wiring layer 315.

In the opening pattern, the contact plug 313 and openings used to expose the top surfaces of the two contact plugs 312 at both sides of the contact plug 313 are continuously formed. By the wiring layer 315, the contact plug 313 and the contact plugs 312 at both sides thereof are connected to each other. In this way, a chain structure where memory cells, each of which includes one transistor and one capacitor connected in parallel, are connected in series is obtained.

As such, even in the ferroelectric memory that has the chain structure, a grain is rarely formed in the Ir film 308b of the lower electrode of the capacitor, and oxygen that is contained in the ferroelectric film 309 is prevented from diffusing into the contact plug 307.

Since oxidization of the contact plug is suppressed, a voltage can be normally applied to the ferroelectric film, and operation performance of the ferroelectric memory can be improved. Accordingly, a semiconductor memory device having high reliability can be realized.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a semiconductor substrate;
an impurity diffusion layer that is formed at a surface portion of the semiconductor substrate;
an interlayer insulating film that is formed on the semiconductor substrate;
a contact plug that penetrates the interlayer insulating film, has a top surface formed higher than a top surface of the interlayer insulating film, a region having a convex shape formed higher than the top surface of the interlayer insulating film, and contacts the impurity diffusion layer;
a lower capacitor electrode film that is formed on the contact plug and a predetermined region of the interlayer insulating film;
a ferroelectric film that is formed on the lower capacitor electrode film; and
an upper capacitor electrode film that is formed on the ferroelectric film.

2. The semiconductor memory device according to claim 1,
wherein the contact plug includes:
a first metal film that penetrates the interlayer insulating film, has a top surface formed higher than the top surface of the interlayer insulating film, and contacts the impurity diffusion layer; and
a second metal film that is formed in a convex shape in an outer circumferential portion of the first metal film on the interlayer insulating film.

3. The semiconductor memory device according to claim 1,
wherein the contact plug includes:
a first metal film that penetrates the interlayer insulating film, has a top surface formed higher than the top surface of the interlayer insulating film, and contacts the impurity diffusion layer; and
a second metal film that is buried in an upper portion of the first metal film.

4. The semiconductor memory device according to claim 3,
wherein the contact plug further includes:
a third metal film that is formed in a convex shape in an outer circumferential portion of the first metal film on the interlayer insulating film and contains the same material as the second metal film.

5. The semiconductor memory device according to claim 1,
wherein the lower capacitor electrode film has a barrier layer and a noble metal film formed on the barrier layer.

6. A semiconductor memory device comprising:
a semiconductor substrate;
first to third impurity diffusion layers that are formed at a surface portion of the semiconductor substrate at predetermined intervals;
a first interlayer insulating film that is formed on the semiconductor substrate;
a first contact plug that is formed in the first interlayer insulating film and is connected to the first impurity diffusion layer;
a second contact plug that is formed in the first interlayer insulating film and is connected to the second impurity diffusion layer;
a third contact plug that is formed in the first interlayer insulating film and is connected to the third impurity diffusion layer;
a fourth contact plug that is formed on the first contact plug and has first and second convex portions formed on a top surface thereof;
a fifth contact plug that is formed on the second contact plug;
a sixth contact plug that is formed on the third connect plug and has third and fourth convex portions formed on a top surface thereof;
a first capacitor that is formed on the first convex portion and has a lower electrode film, a ferroelectric film, and an upper electrode film, which are sequentially laminated;
a second capacitor that is formed on the second convex portion and has a lower electrode film, a ferroelectric film, and an upper electrode film, which are sequentially laminated;
a third capacitor that is formed on the third convex portion and has a lower electrode film, a ferroelectric film, and an upper electrode film, which are sequentially laminated;
a fourth capacitor that is formed on the fourth convex portion and has a lower electrode film, a ferroelectric film, and an upper electrode film, which are sequentially laminated;
a second interlayer insulating film that is formed to cover the first to fourth capacitors and the first to third contact plugs;
a seventh contact plug that is formed in the second interlayer insulating film and is connected to the fifth contact plug;
an eight contact plug that is formed in the second interlayer insulating film and is connected to the upper electrode film of the first capacitor;
a ninth contact plug that is formed in the second interlayer insulating film and is connected to the upper electrode film of the third capacitor; and
a wiring layer that is formed on the second interlayer insulating film and is connected to the seventh to ninth contact plugs.

7. A method for manufacturing a semiconductor memory device, comprising:
forming an impurity diffusion layer at a surface portion of a semiconductor substrate;
forming an interlayer insulating film on the semiconductor substrate:
forming an opening penetrating the interlayer insulating film and exposing a top surface of the impurity diffusion layer;
burying a metal film in the opening;
removing the interlayer insulating film from a top surface with a predetermined thickness to expose an upper portion of the metal film;
performing a chemical mechanical polishing (CMP) process to remove an upper end of the metal film; and
forming a capacitor having a lower electrode film, a ferroelectric film, and an upper electrode film, which are sequentially laminated, on the metal film.

8. The method according to claim 7,
wherein, when a cavity is formed in the metal film buried in the opening, a second metal film is buried in the cavity.

9. The method according to claim 7,
wherein first and second insulating films are sequentially laminated to form the interlayer insulating film, and
the second insulating film is removed to expose the upper portion of the metal film.

10. A method for manufacturing a semiconductor memory device, comprising:
forming an impurity diffusion layer at a surface portion of a semiconductor substrate;
forming an interlayer insulating film on the semiconductor substrate;
forming an opening penetrating the interlayer insulating film and exposing a top surface of the impurity diffusion layer;
burying a first metal film in the opening;
removing the interlayer insulating film from a top surface with a predetermined thickness to expose an upper portion of the first metal film;
forming a second metal film having a convex shape in an outer circumferential portion of the first metal film on the interlayer insulating film; and
forming a capacitor having a lower electrode film, a ferroelectric film, and an upper electrode film, which are sequentially laminated, on the first and second metal films.

11. The method according to claim 10,
wherein the second metal film is formed to cover the interlayer insulating film and the first metal film, after the upper portion of the first metal film is exposed, and
etching back the second metal film to expose the top surfaces of the first metal film and the interlayer insulating film, and causing the second metal film to remain in a convex shape in the outer circumferential portion of the first metal film.

12. The method according to claim 11,
wherein, when a cavity is formed in the first metal film buried in the opening, the second metal film is formed to bury the cavity.

13. The method according to claim 10,
wherein first and second insulating films are sequentially laminated to form the interlayer insulating film, and
the second insulating film is removed to expose the upper portion of the first metal film.

14. A method for manufacturing a semiconductor memory device, comprising:
forming first to third impurity diffusion layers at a surface portion of a semiconductor substrate at predetermined intervals;
forming a first interlayer insulating film on the semiconductor substrate;
forming first to third openings penetrating the first interlayer insulating film and exposing top surfaces of the first to third impurity diffusion layers, respectively;
burying a first metal film in the first to third openings to form first to third contact plugs;
forming a second interlayer insulating film on the first interlayer insulating film and the first to third contact plugs;
forming a fourth opening penetrating the second interlayer insulating film and exposing a top surface of the first contact plug, a fifth opening exposing a top surface of the second contact plug and having a width narrower than that of the fourth opening, and a sixth opening exposing a top surface of the third contact plug and having a width wider than that of the fifth opening;
burying a second metal film in the fourth to sixth openings to form fourth to sixth contact plugs;
forming a resist film in first and second predetermined regions on the fourth contact plug and third and fourth predetermined regions on the sixth contact plug;
removing the second interlayer insulating film and the fourth to sixth contact plugs with a predetermined thickness, using the resist film as a mask;
removing the resist film;
performing a chemical mechanical polishing (CMP) process to remove an upper end of the fourth contact plug of the first and second predetermined regions and an upper end of the sixth contact plug of the third and fourth predetermined regions;
forming first to fourth capacitors having a lower electrode film, a ferroelectric film, and an upper electrode film, which are sequentially laminated, in the first and second predetermined regions on the fourth contact plug and the third and fourth predetermined regions on the sixth contact plug, respectively;
forming a third interlayer insulating film to cover the first to fourth capacitors, the second interlayer insulating film, and the fourth to sixth contact plugs;
forming a seventh opening penetrating the third interlayer insulating film and exposing a top surface of the fifth contact plug;
burying a third metal film in the seventh opening to form a seventh contact plug;
forming eighth and ninth openings penetrating the third interlayer insulating film and exposing a top surface of the upper electrode film of the first capacitor and a top surface of the upper electrode film of the third capacitor, respectively;
burying a fourth metal film in the eighth and ninth openings to form eighth and ninth contact plugs;
forming a fourth interlayer insulating film on the third interlayer insulating film and the seventh to ninth contact plugs;
forming a tenth opening penetrating the fourth interlayer insulating film and exposing top surfaces of the seventh to ninth contact plugs; and
burying a fifth metal film in the tenth opening to form a wiring layer contacting the seventh to ninth contact plugs.
